(19) United States
(12) Patent Application Publication
(10) Pub. No.: US 2012/0055396 A1
(43) Pub. Date: Mar. 8, 2012

(54) INTERMEDIATE MATERIALS AND METHODS FOR HIGH-TEMPERATURE APPLICATIONS

(75) Inventors: Govindhan Dhanaraj, Merrimack, NH (US); Chandra Khattak, Nashua, NH (US); Ben Korzeniowski, Milford, NH (US); Carl Richard Schwerdtfeger, JR., Wilton, NH (US); Raj Shetty, Nashua, NH (US)

(73) Assignee: ADVANCED RENEWABLEENERGY COMPANY LLC, Nashua, NH (US)

(21) Appl. No.: 13/278,823

(22) Filed: Oct. 21, 2011

Related U.S. Application Data
(63) Continuation-in-part of application No. 13/095,073, filed on Apr. 27, 2011.
Application No. 13/095,073 is a continuation-in-part of application No. 12/588,656, filed on Oct. 22, 2009.
Application No. 12/588,656 is a continuation-in-part of application No. 12/909,471, filed on Oct. 21, 2010.
Application No. 12/909,471 is a continuation-in-part of application No. 12/588,656, filed on Oct. 22, 2009.
(60) Provisional application No. 61/108,213, filed on Oct. 24, 2008.

(51) Int. Cl. C30B 11/02

(52) U.S. Cl. 117/81; 117/223

(57) ABSTRACT

A system and method for growing crystals is described. The system includes a crucible, a shaft adapted to support the crucible, and an intermediate material between the crucible and the shaft having a coating directly applied to contact surfaces of the crucible and the shaft. The coating includes a compound, such as, a carbide, nitride, oxide, or boride. The method for growing a crystal includes providing an intermediate material between contact surfaces between a shaft and a crucible supported by the shaft prior to melting a charge material in the crucible.

### CROSS-REFERENCE TO RELATED APPLICATIONS

This application is a continuation-in-part of co-pending U.S. Non-provisional patent application Ser. No. 13/095,073, filed Apr. 27, 2011 and U.S. Non-provisional patent application Ser. No. 12/909,471, filed Oct. 21, 2010, both of which are continuations-in-part of co-pending U.S. Non-provisional patent application Ser. No. 12/588,656, Published Application No. US 2010-0101387, filed Oct. 22, 2009. U.S. Non-provisional patent application Ser. No. 12/588,656 claims priority under 35 U.S.C. 119 to U.S. Provisional Application No. 61/108,213, filed Oc. 24, 2008. All of the aforementioned applications are hereby incorporated herein by reference in their entireties.

### FIELD OF TECHNOLOGY

The present disclosure relates to a field of growing crystals and more particularly relates to methods and systems for growing large, highly pure crystals of, for example, sapphire.

### BACKGROUND

In many high-temperature material processing applications, a material is melted in a crucible to temperatures above the melting point of the material. Typically, the crucible is supported inside a furnace by a support, such as a shaft, and the crucible and shaft are both formed from a refractory material, such as a refractory metal. Often these processing applications involve large quantities of molten material. Such large quantities, in addition to the weight of the crucible itself can result in high loads at the contact areas between the crucible and its support. In addition, a production cycle can occur over extended periods of time, thus requiring prolonged exposure of the shaft and crucible to high temperatures. Under prolonged high temperature and load conditions, contact surfaces of the shaft and crucible have an undesirable tendency to fuse together. In addition, the presence of any contaminants on the contact surfaces of the shaft and crucible can exacerbate the problem. What is needed is a system and method for high temperature processing applications free of the aforementioned problem.

### SUMMARY

In one aspect, the present disclosure is directed to a system for high-temperature material processing. The system includes a crucible, a shaft adapted to support the crucible, and an intermediate material between the crucible and the shaft. The intermediate material is a disc or a coating directly applied to contact surfaces of the crucible and the shaft.

In another aspect, the present disclosure is directed to a system for growing crystals. The system includes a crucible, at least one heating element adapted to heat the crucible, a seed cooling component adapted to receive a coolant fluid to cool a portion of the crucible, an intermediate material between the crucible and the seed cooling component, a gradient control device comprising thermal insulation and adapted to vary a temperature gradient inside the crucible, and an insulating element substantially surrounding the crucible, heating element, and gradient control device. The gradient control device and the crucible are independently movable with respect to each other and the at least one heating element.

In yet another aspect, the present disclosure is directed to a method for growing a crystal. The method includes substantially fully covering a seed crystal in a charge material in a crucible, using a heat source to melt the charge material, flowing cooling fluid through a seed cooling component in thermal communication with the crucible to keep the seed crystal at least partially intact as the charge material melts, allowing at least a portion of the seed crystal to melt into the molten charge material, continually growing the crystal by reducing the temperature of the heat source, moving the molten charge material and seed crystal from the heat source, increasing a rate of cooling of the seed crystal, and varying a temperature gradient inside the crucible. The method further includes providing an intermediate material between the crucible and the seed cooling component comprising a disc or a coating that is directly applied to contact surfaces of the crucible and the seed cooling component prior to using a heat source to melt the charge material.

In yet another aspect, the present disclosure is directed to a method for high-temperature material processing. The method includes providing an intermediate material between a shaft and a crucible supported by the shaft prior melting a charge material, the intermediate material being a disc or a coating directly applied to contact surfaces of the crucible.

### BRIEF DESCRIPTION OF THE DRAWINGS

Various preferred embodiments are described herein with reference to the drawings, wherein:

FIG. 1 is a cross-sectional view of a furnace used in growing a single crystal along the c-axis, according to one embodiment;

FIGS. 2 through 4 illustrate a process of formation of a cored c-axis cylindrical ingot from a seed crystal, according to one embodiment;

FIG. 5 is a process flowchart of an exemplary method of certain steps for growing a single crystal about the c-axis using a furnace, such as the one shown in FIG. 1, and thereafter producing wafers using the single crystal, according to one embodiment;

FIG. 6 illustrates an intermediate material between a seed cooling shaft and a crucible of a crystal growth system according to one embodiment of the present disclosure;

FIG. 7 is a graphical representation of two different temperature gradients; and

FIG. 8 is a table summarizing the state of various parameters during various stages of operation of an embodiment of the present disclosure.

### DETAILED DESCRIPTION

The present disclosure describes the use of intermediate materials, such as discs and/or coatings, to facilitate separation between a shaft and a crucible. These intermediate materials are useful in material processing applications where prevention of fusion between a crucible and supporting shaft is wanted. Such applications are typically high-temperature applications where a crucible and supporting shaft are in high-load contact with each other. Such applications include, but are not limited to crystal growing, directional solidification, casting, and foundry applications. Without intending to be limited to any particular application, the present disclosure describes the use of such intermediate materials with respect to CHES crystal growing furnaces, which are described in U.S. patent application Ser. Nos. 13/095,073, 12/909,471, 12/588,656, and 61/108,213 the entireties of each of which are incorporated herein by reference.

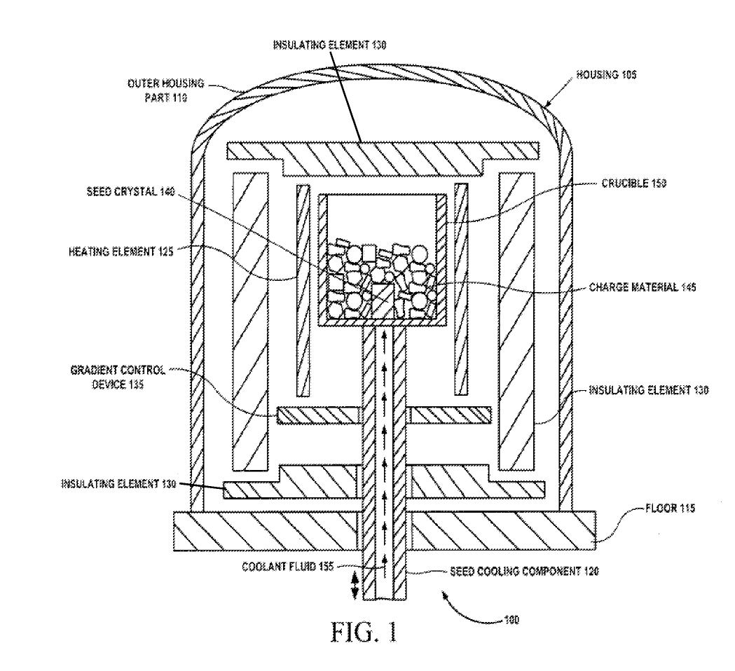

FIG. 1 is a cross-sectional view of a furnace 100 used in one embodiment of the crystal growing system and method of the present disclosure. In FIG. 1, the furnace 100 may include a housing 105. The housing 105 may include an outer housing part 110 and a floor 115. The outer housing part 110 and the floor 115 together form a chamber, which in certain embodiments may be a double walled, water cooled chamber. The furnace 100 also may include an insulating element 130, a seed cooling component 120, at least one heating element 125, a gradient control device (GCD) 135 and a crucible 150, all of which are enclosed in the outer housing part 110. The elements enclosed in the outer housing part 110 form a “heat zone.” Thus, the heating element 125, crucible 150, gradient control device 135, insulating element 130, and a portion of the seed cooling component 120 are all part of the heat zone. References throughout this application to the heat zone, the melt, the furnace and the chamber may, where context indicates, refer to this interior portion of the chamber.

The insulating element 130 substantially surrounds the seed cooling component 120, the heating element(s) 125 and the crucible 150 and minimizes heat transfer external to the insulating element. The insulating element 130 may be made of material graphite, a high temperature ceramic material, a refractory metal, or an alloy of refractory metals.

The heating element(s) 125 substantially surrounds the seed cooling component 120 and the crucible 150 and is adapted to heat the crucible 150. The heating element may comprise graphite or a refractory metal, such as tantalum, molybdenum, or tungsten, or an alloy of refractory metals. The heating element(s) 125 is adapted to substantially slowly lower the temperature inside the heat zone of the chamber during crystal growth, for example, as slow as 0.02° C./hr

The crucible 150 holds a seed crystal 140 (e.g., D shaped, circular shaped, etc.) and a charge material 145 (e.g., sapphire (Al₂O₃), silicon (Si), calcium fluoride (CaF₂), sodium iodide (NaI), and other halide group salt crystals). The crucible 150 may be made of a refractory metal, such as molybdenum, tungsten, or alloys thereof, or a non-metallic material, such as graphite (C), boron nitride (BN), and the like. In embodiments where the crucible is tungsten, the crucible may be reused in subsequent operations. This presents a cost savings over other crucibles, such as molybdenum crucibles, which, in high temperature crystal growth applications like sapphire growth, are typically one-time use crucibles. In some embodiments, the crucible 150 is capable of holding 0.3 to 450 kilograms of the charge material 145.

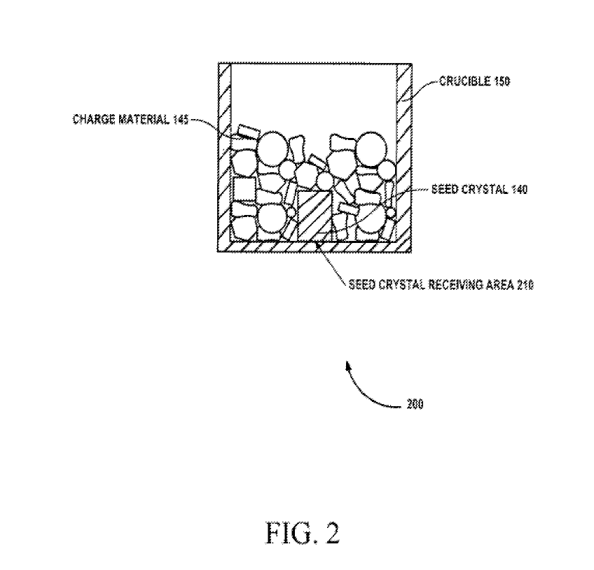

The crucible 150 may include a seed crystal receiving area 210, shown in FIG. 2. The seed crystal receiving area 210 holds the seed crystal 140 in the crucible 150. In the embodiment shown in FIG. 2, the seed crystal receiving area is simply a region at the flat bottom of cylindrical-shaped crucible. However, the seed crystal receiving area may include contours. For example, the seed crystal receiving area may be conical or may include a seed pocket. The seed crystal receiving area may be adapted to fit a seed crystal of particular size and shape in a particular orientation.

In the embodiment shown in FIG. 1, the crucible 150 is supported by the seed cooling component 120 and is movable relative to the heating element(s) 125. The crucible 150 is movable by way of the seed cooling component 120, which can be raised and lowered. The seed cooling component 120 is moved through one or more openings in the floor 115 of the housing 105. As described in further detail below, lowering the crucible via the seed cooling component during the crystal growth phase helps to maintain crystal growth rate and facilitates the growth of a substantially larger crystal.

As shown in the embodiment of FIG. 1, the seed cooling component 120 may be a hollow component (e.g., made of a refractory metal, such as tungsten (W), molybdenum (Mo), niobium (Nb), lanthanum (La), tantalum (Ta), rhenium (Re) or their alloys) that supports and is in thermal communication with a bottom of the crucible 150. The seed cooling component 120 also receives a coolant fluid 155 (e.g., helium (He), neon (Ne) and hydrogen (H)) to cool the supported portion of the crucible 150 through the hollow portion. The flow rate of the coolant fluid entering the seed cooling component can be controlled to adjust the rate of cooling of the seed crystal.

In the case of sapphire growth in a CHES furnace, a charge is melted to temperatures above the melting point of sapphire (2050° C.), so the crucible and the shaft of the seed cooling component are both formed from a refractory metal, such as molybdenum, tungsten, or alloys of molybdenum and tungsten. In certain embodiments, both the seed cooling component 120 and the crucible 150 are made of tungsten. As a result, heat and mass is transferred more easily between the seed cooling component and crucible. The growth cycle of sapphire crystal can take several weeks, thus requiring prolonged exposure of the shaft and crucible to high temperatures. In addition, the weight of the charge material in the crucible and the crucible itself results in a substantial amount of load between the crucible and the shaft. Under prolonged high temperature and load conditions, the contact surfaces of the shaft and crucible (i.e., the surfaces of the shaft and crucible that contact each other) have an undesirable tendency to fuse together. In addition, the presence of any contaminants on the contact surfaces of the shaft and crucible can exacerbate the problem.

Fusion between the crucible and shaft can be prevented by introducing an intermediate material between the shaft and the crucible. The intermediate material may be a disc that is placed between the contact surfaces of the shaft and crucible. In another embodiment, the intermediate material is a disc having a surface that is coated. Alternatively, the intermediate material may be a coating which is directly applied to the contact surfaces of the shaft and crucible.

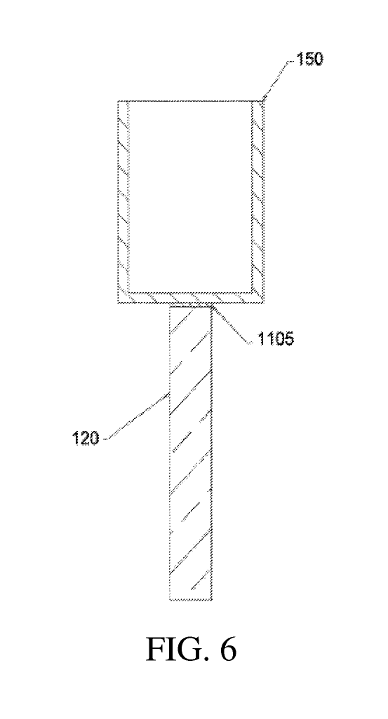

As shown in FIG. 6, the intermediate material is a disc 1105 that prevents direct contact between the contact surfaces of the seed cooling component 120 and the crucible 150. The disc 1105, serves as an intermediate material that prevents fusion between seed cooling component 120 and the crucible 150. In one embodiment, the disc is a thin layer of a refractory material, such as molybdenum, tungsten, or an alloy thereof, positioned between the seed cooling component 120 and crucible 150. The thickness of the disc can be approximately 1 mm or greater.

In another embodiment, the disc is coated to further prevent fusion. Suitable coatings include carbides, nitrides, oxides, silicides, or borides. Suitable carbides include, for example, titanium carbide. Nitrides include, for example, silicon nitride, boron nitride, and titanium nitride. Silicides include, for example, molybdenum silicide, and borides include, for example zirconium boride. In other embodiments, the coating may include an oxide such as stannic oxide, erbia, gadolinia, alumina, yttria, zirconia, or yttria stabilized zirconia. The coating may be applied by spraying or painting, and preferably has a thickness between about 0.1 mm and about 1.0 mm after drying.

In the alternative, the intermediate material may be a coating of a carbide, nitride, oxides, silicide, or boride, described above, that is directly applied to the contact surfaces of the shaft and crucible. The coating may be a mixture, such as a suspension or slurry including one or more of the above described compounds. In one embodiment, the coating is a slurry including yttria powder. The mixture may be water based, based in an alcohol, such as ethanol, or other solvent, such as acetone. In one example, the mixture includes between about 40% and about 60% yttria by weight. The coating may be applied to the contact surfaces, for example, by spraying or painting, and preferably has a thickness between about 0.1 mm and about 1.0 mm after drying. The coating may be applied prior to each crystal growth run. It is preferable that the contact surfaces of the seed cooling component shaft and crucible are cleaned before each application of the coating.

The use of the discs and/or coatings to facilitate separation between the shaft and crucible as described above is not limited to application in CHES furnaces. These intermediate materials are also useful in other material processing applications where prevention of fusion between a crucible and supporting shaft is wanted, such as crystal growing, directional solidification, casting, and foundry applications. For example, the intermediate materials may be useful in Vertical Bridgman furnaces. The shaft need not be a seed cooling component, i.e., the shaft may not provide significant heat removal from the bottom of the crucible, but rather may simply provide physical support for the crucible. Thus, the system may include a crucible, a shaft adapted to support the crucible, and an intermediate material between the crucible and the shaft comprising a disc or a coating directly applied to contact surfaces of the crucible and the shaft.

The gradient control device (GCD) 135 varies the temperature gradient of the melt and/or crystal inside the crucible during different stages of operation. The position of the GCD can be adjusted to control the degree of heat transport near the bottom of the crucible (i.e., the vicinity of the seed crystal), thereby providing the ability to vary the temperature as desired. The GCD comprises thermal insulation. The thermal insulation may comprise a refractory metal, such as tungsten or molybdenum, or may be formed from graphite felt. In some embodiments, the insulation of the GCD comprises radiation shields. Each radiation shield may be formed from a refractory metal, such as tungsten or molybdenum, or alloys thereof. In one embodiment, at least one radiation shield is formed from tungsten. In another embodiment, an innermost radiation shield (i.e., shield closest to the crucible) is formed from tungsten, while an outermost radiation shield (i.e., shield furthest from the crucible) is formed from molybdenum. The radiation shields may be stacked together and spaced apart with spacers formed from the same material as the shields.

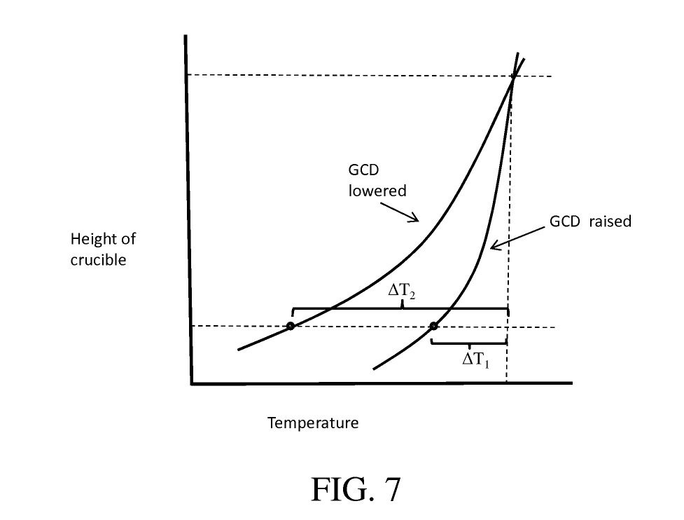

In the embodiment shown in FIG. 1, the GCD is movable relative to the seed cooling component 120, the heating element(s) 125, the insulating element 130 and the crucible 150 over a range of positions. The GCD and the crucible 150 may also move independently with respect to each other. The mobility of the GCD allows it to control the degree of heat transport from the vicinity of the bottom of the crucible, thereby varying the temperature gradient of the contents of the crucible (e.g., growing crystal and melt) as desired. In the embodiment shown in FIG. 1, the GCD is movable along the seed cooling component shaft. In the embodiment shown in FIG. 1, the heat shields of the GCD include openings to allow the GCD to move along the shaft of the seed cooling component. The higher the GCD is positioned on the shaft, the closer it is to the heating element. In a raised position, such as the one shown in FIG. 1, the GCD insulates the vicinity of the bottom of the crucible and seed crystal. As the GCD is moved further from the heating element 125, heat in the vicinity of the bottom of the crucible is allowed to dissipate, and the temperature gradient along the crucible increases. The increase of the temperature gradient effected by the GCD is illustrated in FIG. 7. The figure shows two temperature gradient curves along the height of a crucible in the system of the present disclosure. The curve on the right represents a temperature gradient along the crucible when the GCD is in a raised position, while the curve on the left represents a temperature gradient when the GCD is in a lowered position. The temperature gradient along the height of the crucible in the raised position is ΔT₁. Placing the GCD in the lower position results in an increased temperature gradient along the crucible, ΔT₂. Different temperature gradients are desirable during the various stages of crystal growth. During melting, a decreased gradient helps to ensure that all the charge is melted and the temperature of the melt is as homogenous as possible. During growth of the crystal, the increased gradient ensures controlled crystal growth from the seed to the top of the melt. During annealing of the crystal, a decreased temperature gradient is typically more desirable. Thus, lowering the GCD during crystal growth and raising the GCD during melting and annealing can achieve a larger single crystal of high quality.

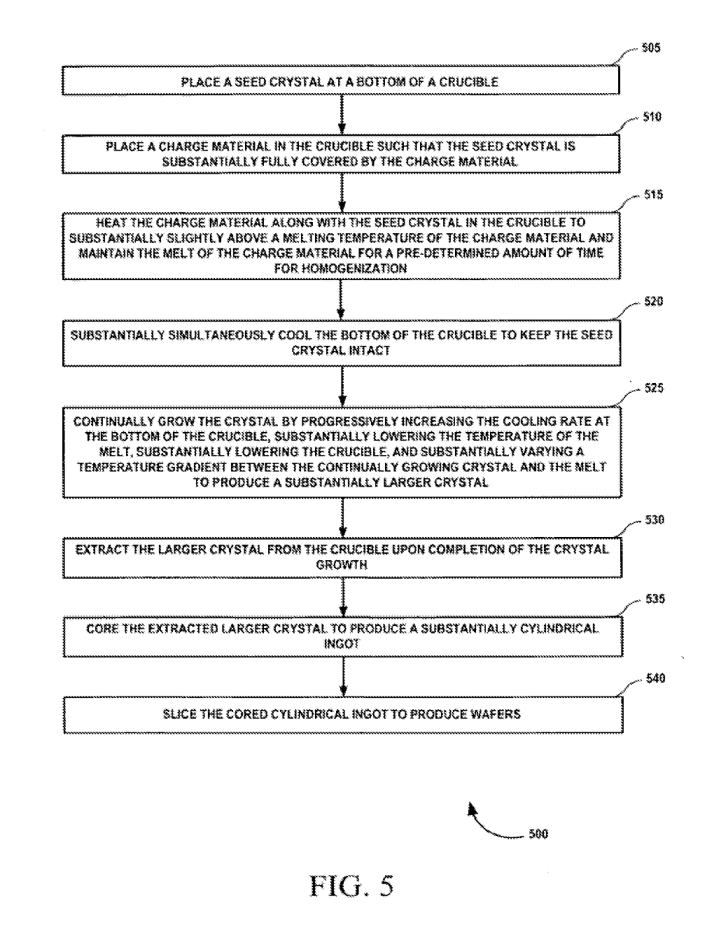

FIG. 5 is a process flowchart 500 of an exemplary method of growing a single crystal about the c-axis using the furnace 100, such as the one shown in FIG. 1, and thereafter producing wafers using the single crystal, according to one embodiment.

In step 505, a seed crystal (e.g., sapphire seed crystal) is placed at a bottom of the crucible 150, for example, in the seed crystal receiving area 210, as shown in FIG. 2. In step 510, a charge material (e.g., a sapphire charge material) is placed in the crucible 150 such that the seed crystal 140 is substantially fully covered by the charge material 14, as shown in FIG. 2. Then, the crucible 150 with the charge material and the seed crystal is loaded into the furnace 100.

In step 515, power to the heating element 125 is supplied to heat the charge material 145 along with the seed crystal 140 in the crucible 150 to substantially slightly above a melting temperature of the charge material 145. For example, in the case of sapphire charge material, the crucible may be heated in the range of about 2040 to 2100° C. The crucible may be raised and/or maintained in a raised position at this time. The GCD can be raised and/or maintained in a raised position to minimize the temperature gradient and ensure a homogenous melt. Once the charge material 145 is completely molten, the molten charge material (also referred to as the “melt” of the charge material) is maintained for a predetermined amount of time for homogenization, typically 1-24 hours.

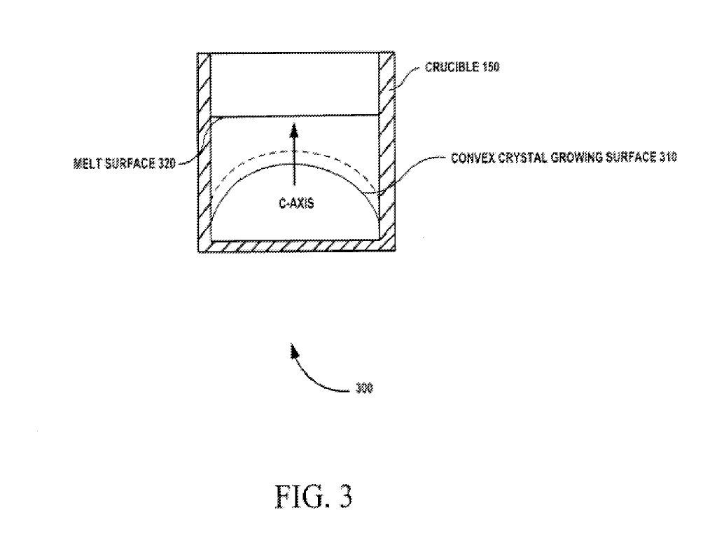

In step 520, the bottom of the crucible 150 and seed crystal 140 may be cooled by flowing the coolant fluid 155 through the seed cooling component 120 simultaneously to the heating of the charge material 145 in step 515. In some embodiments, the bottom of the crucible 150 and seed crystal 140 are cooled using helium when the melt of the charge material is above the melting temperature. For example, helium may be flown through the seed cooling component 120 supporting the bottom of the crucible 150 at a rate approximately in the range of about 10 to 100 lpm. At least a portion of the seed crystal is allowed to melt into the molten charge material, and the bottom of the crucible 150 is cooled such that the seed crystal 140 remains intact and is not melted completely. In the case of a seed crystal oriented along the c-axis, the minimal desired melting may include melting a portion of a top surface (e.g., c-face) of the seed crystal to form a convex crystal growing surface, as shown in FIG. 3. A small portion of the top surface of the seed crystal 140 is melted by increasing the temperature of the melt and/or reducing the flow rate of helium (e.g., from 90 lpm to 80 lpm) through the seed cooling component 201, resulting in a convex (or dome) shaped crystal. The convex crystal growing surface is a true non-habit face (e.g., not the true c-face) having multi-steps made of different orientations. The convex crystal growing surface helps stabilize the growth process of the crystal substantially along the c-axis.

In step 525, growth of the crystal is initiated (step 525). In one or more embodiments, as the crystal grows, the cooling rate at the bottom of the crucible 150 is increased progressively by ramping up the flow rate of the coolant fluid 155 through the seed cooling component 120. For example, the flow rate may be increased up to 600 lpm of helium over a period of 24-96 hours. Concurrently, the temperature of the melt may be substantially lowered by substantially slowly lowering the temperature of the heating element(s) 125, for example, at a rate of about 0.02-10° C./hr. As a result, the melt is cooled and a temperature gradient is established between the seed crystal and the melt. The temperature gradient can be substantially increased to ensure continued controlled growth of the crystal and to produce a larger solidified single crystal. This is accomplished by lowering the GCD 135 and/or maintaining the GCD in a lowered position during crystal growth. Lowering the GCD increases the rate of heat transfer from the vicinity of the seed crystal, thereby increasing the temperature gradient along the growing crystal and melt. For example, the GCD may be lowered at a rate of about 0.1-5 mm/hr.

Further, as the crystal grows taller, the distance of the solid-liquid isotherm from the bottom of the crucible increases and the effect of the coolant fluid 155 diminishes, causing the growth rate of the crystal to slow down steadily. To compensate for the reduced growth rate of the crystal, the crucible 150 may be lowered by moving the seed cooling component 120. Lowering the crucible increases the distance between the crucible and the heating element, thereby allowing the melt to cool and maintaining the growth rate of the crystal. In one embodiment, the crucible is lowered at a rate of about 0.1-5 mm/hr.

On completion of the crystal growth, the solidified crystal undergoes an annealing step where the crystal is held at a certain temperature below the melt temperature of the crystal for a certain amount of time before being allowed to cool to room temperature. For example, the heating element is held at a temperature in the range of about 50-200° C. below the melting point of the crystal material for a time period sufficient to achieve temperature homogeneity throughout the crystal. This may be achieved by lowering the temperature of the heating element(s) 125, reducing the flow of the coolant fluid 155 to slow removal of heat from the bottom of the crucible 150, and moving the GCD 135 to a favorable position to reduce the temperature gradient. For example, the temperature of the heating element can be lowered at a rate of about 0.02 to 50° C./hr and the GCD can be raised during the annealing stage in order to reduce the temperature gradient, thereby bringing the solidified crystal to a more uniform temperature. In addition, the crucible can be raised or maintained in the crystal growth position during the annealing stage to ensure annealing of the solidified single crystal prior to cooling.

After annealing, the temperature of the furnace 100 is gradually reduced to gradually and uniformly cool the annealed crystal to room temperature. The GCD and crucible both may be maintained in the anneal position or may be lowered at this time. The rate of coolant fluid to the seed cooling component may be further reduced, or the anneal rate may be maintained. Further, inert gas pressure inside the furnace 100 can be increased before the crystal is extracted from the furnace 100.

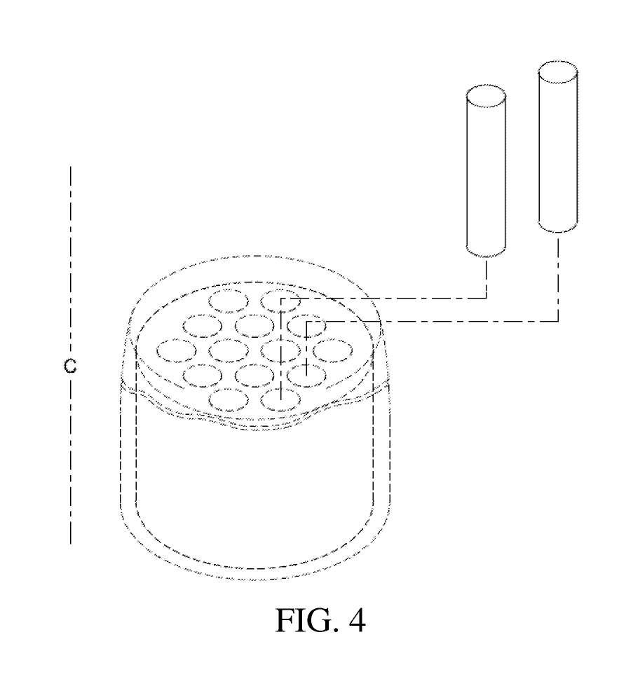

In step 530, the crystal is extracted from the crucible 150 upon completion of the crystal growth. In step 535, the extracted crystal is cored to produce a substantially cylindrical ingot. In one embodiment, the cylindrical ingot is produced by coring substantially perpendicular to the top surface of the extracted crystal, as shown in FIG. 4. In step 540, the cored cylindrical ingot is sliced to produce wafers. It should be noted that while FIG. 5 depicts steps in an exemplary method, in alternative embodiments that would be understood by one of ordinary skill in the art, certain steps may be altered or omitted, the order of steps may be adjusted, or additional steps may be included. Such additional steps may include evacuating the chamber, backfilling the chamber with a gas, such as argon, and the like.

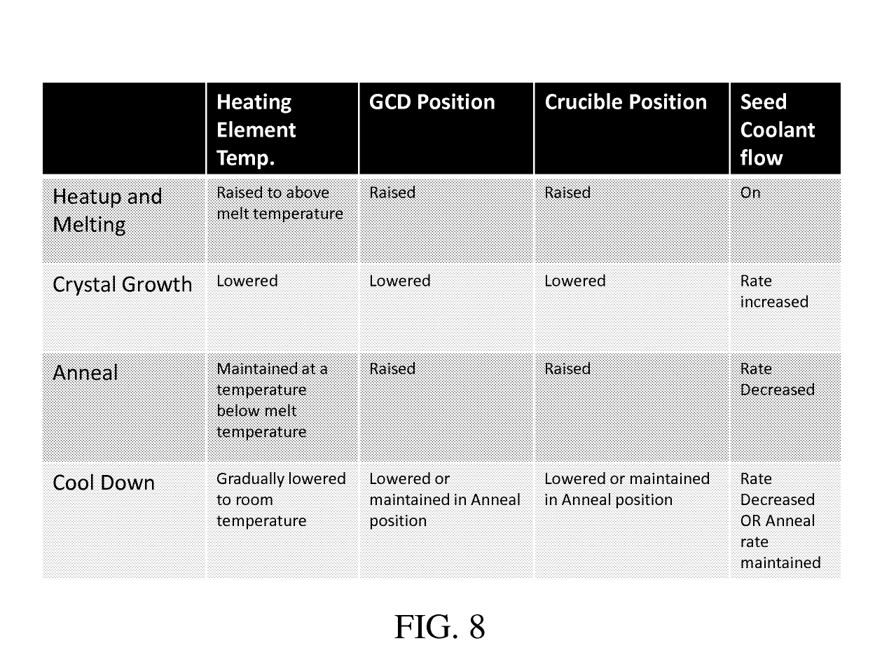

As described above, the temperature of the heating element 125, the position of the crucible 150, the flow rate of the cooling fluid in the seed cooling component, and the position of the GCD 135 can be manipulated during the various stages of the process to optimize the production of a solid monocrystal. An example of this is illustrated in FIG. 8, which summarizes the state of these parameters during various stages in one embodiment of the present disclosure.

Although the present embodiments have been described with reference to specific example embodiments, it will be evident that various modifications and changes may be made to these embodiments without departing from the broader spirit and scope of the various embodiments. In addition, it will be appreciated that the various operations, processes, and methods disclosed herein may be performed in any order. Accordingly, the specification and drawings are to be regarded in an illustrative rather than a restrictive sense.

What is claimed is:

1. A system, comprising:
a crucible;
a shaft adapted to support the crucible; and
an intermediate material between the crucible and the shaft comprising a disc or a coating directly applied to contact surfaces of the crucible and the shaft.

2. The system of claim 1, wherein the coating comprises a compound selected from the group consisting of carbides, nitrides, oxides, and borides.

3. The system of claim 2, wherein the coating comprises an oxide selected from the group consisting of stannic oxide, erbia, gadolinia, alumina, yttria, zirconia, and yttria stabilized zirconia.

4. The system of claim 3, wherein the coating comprises yttria.

5. The system of claim 1, wherein the disc comprises a refractory material selected from the group consisting molybdenum, tungsten, and alloys thereof.

6. The method of claim 1, wherein a surface of the disc has a coating comprising a compound selected from the group consisting of carbides, nitrides, oxides, and borides.

7. The system of claim 6, wherein the coating comprises an oxide selected from the group consisting of stannic oxide, erbia, gadolinia, alumina, yttria, zirconia, and yttria stabilized zirconia.

8. A system for growing crystals, comprising:
a crucible;
at least one heating element adapted to heat the crucible;
a seed cooling component adapted to receive a coolant fluid to cool a portion of the crucible;
an intermediate material between the crucible and the seed cooling component;
a gradient control device comprising thermal insulation and adapted to vary a temperature gradient inside the crucible; and
an insulating element substantially surrounding the crucible, heating element, and
gradient control device,
wherein the gradient control device and the crucible are independently movable with respect to each other and the at least one heating element.

9. The system of claim 8, wherein the intermediate material comprises a coating directly applied to contact surfaces of the crucible and the seed cooling component, the coating comprising a compound selected from the group consisting of carbides, nitrides, oxides, and borides.

10. The system of claim 9, wherein the coating comprises an oxide selected from the group consisting of stannic oxide, erbia, gadolinia, alumina, yttria, zirconia, and yttria stabilized zirconia.

11. The system of claim 10, wherein the coating comprises yttria

12. The system of claim 8, wherein the intermediate material comprises a disc formed from a refractory material selected from the group consisting of molybdenum, tungsten, and alloys thereof.

13. The system of claim 12, wherein a surface of the disc has a coating comprising a compound selected from the group consisting of carbides, nitrides, oxides, and borides.

14. A method for growing a crystal, comprising:
substantially fully covering a seed crystal in a charge material in a crucible;
using a heat source to melt the charge material;
flowing cooling fluid through a seed cooling component in thermal communication with the crucible to keep the seed crystal at least partially intact as the charge material melts;
allowing at least a portion of the seed crystal to melt into the molten charge material;
continually growing the crystal by reducing the temperature of the heat source, moving the molten charge material and seed crystal from the heat source, increasing a rate of cooling of the seed crystal, and varying a temperature gradient inside the crucible; and
providing an intermediate material between the crucible and the seed cooling component comprising a disc or a coating directly applied to contact surfaces of the crucible and the seed cooling component prior to using a heat source to melt the charge material.

15. A method, comprising:
providing an intermediate material between a shaft and a crucible supported by the shaft prior melting a charge material, the intermediate material being a disc or a coating directly applied to contact surfaces of the crucible.

16. The method of claim 15, wherein the coating comprises a compound selected from the group consisting of carbides, nitrides, oxides, and borides.

17. The method of claim 16, wherein the coating comprises an oxide selected from the group consisting of stannic oxide, erbia, gadolinia, alumina, yttria, zirconia, and yttria stabilized zirconia.

18. The method of claim 17, wherein the coating comprises yttria.

19. The method of claim 15, wherein the disc is formed from a refractory material selected from the group consisting of molybdenum, tungsten, and alloys thereof.

20. The method of claim 19, wherein a surface of the disc has a coating comprising a compound selected from the group consisting of alumina, yttria, zirconia, and yttria stabilized zirconia.
